(19) United States
(12) Patent Application Publication
(10) Pub. No.: US 2023/0392775 A1
(43) Pub. Date: Dec. 7, 2023

(54) HIGH CURRENT SWITCH WITH THREE-STATE ILLUMINATED KNOB

(71) Applicant: AUDIO ACCESSORIES GROUP, LLC, Tempe, AZ (US)

(72) Inventors: Larry Vansickel, Phoenix, AZ (US); Hai Wang, NINGBO (CN); Dong Yang, NINGBO (CN); Dong Gu Wen, NINGBO (CN)

(21) Appl. No.: 17/831,325

(22) Filed: Jun. 2, 2022

(51) Int. Cl. F21V 23/04; H01H 19/02; H01H 19/14; H05K 7/14; H05K 1/18

(52) U.S. Cl. CPC F21V 23/0407; H01H 19/025; H01H 19/14; H05K 7/1427; H05K 1/181; H05K 2201/10106; F21Y 2115/10

(57) ABSTRACT

A high-current switch for circuits above 25 amperes having an extended rotary knob supporting a PCB safely distant from the heat source of the high-current being switched. The PCB carries LEDs, a voltage meter, and a microprocessor to control LEDs OFF when the rotary knob is in the OFF position, ON when the rotary knob is in the ON position, and flashing when the switch circuit voltage falls below a predetermined value. Various colors of LEDs may be used, with a difference between the flashing color and the ON color. The PCB is covered by a windowed cover at the top of the knob.

### FIELD OF ART

The present invention relates to high-current (above 25 amperes) switches, such as those used in battery-powered systems. The present invention more particularly relates to a high-current switch with a knob that provides illumination to indicate ON, turns illumination OFF when the switch is in the OFF position, and illuminates flashing red if the voltage in the switched circuit falls below a predetermined level.

### BACKGROUND OF THE INVENTION

All the high-current switches in market have no LED indicators. High-current switches generate a lot of heat within the switch housing due to resistance in the switch circuit. Heat limits LED lifespan. It is hard to tell if the circuit has been cut off or not, especially in the night. Many vehicles, such as UTV/ATV, RV, Off-Road etc., are facing battery draining issues. Prior art high-current switches have no indicator if the voltage drops to a warning line. Only low current switches (below 25 Amperes) have LED indicators built-in, because there isn't much heat generated in a small switch housing.

### SUMMARY OF THE INVENTION

The present invention provides a high-current switch having a knob with a top portion that supports a printed circuit board (PCB) that includes light emitting diodes (LEDs), a voltage sensor, and an alarm circuit to flash the LEDs when voltage lowers to a predetermined level. The knob is sufficiently isolated from the heat, via distance and seals, of the switching circuit that the PCB is not degraded by the heat.

### DESCRIPTION OF THE FIGURES OF THE DRAWINGS

The present invention will hereinafter be described in conjunction with the following drawing figures, wherein like numerals denote like elements, and

FIG. 1 is a photographic view illustrating an exemplary first embodiment of a high-current switch on an exemplary embodiment of a switch housing, according to a preferred embodiment of the present invention;

FIG. 2 is an exploded perspective view illustrating the exemplary first embodiment of the high-current switch of FIG. 1, according to a preferred embodiment of the present invention;

FIG. 3 is a front elevation view illustrating the exemplary first embodiment of the high-current switch of FIG. 1, according to a preferred embodiment of the present invention;

FIG. 4 is a side elevation view illustrating the exemplary first embodiment of the high-current switch of FIG. 1, according to a preferred embodiment of the present invention;

FIG. 5 is a bottom plan view illustrating the exemplary first embodiment of the high-current switch of FIG. 1, according to a preferred embodiment of the present invention;

FIG. 6 is a top plan view illustrating the first exemplary embodiment of the high-current switch of FIG. 1 in an ON position, according to a preferred embodiment of the present invention;

FIG. 7 is a top plan view illustrating the first exemplary embodiment of the high-current switch of FIG. 1 in an OFF position, according to a preferred embodiment of the present invention;

FIG. 8 is a top perspective view illustrating the first exemplary embodiment of the high-current switch of FIG. 1, according to a preferred embodiment of the present invention; and

FIG. 9 is a bottom perspective view illustrating the first exemplary embodiment of the high-current switch of FIG. 1, according to a preferred embodiment of the present invention;

FIG. 10 is a cutaway side elevation view illustrating an exemplary embodiment of a high-current insulated wire connected to an exemplary switch pole of the high-current switch of FIG. 1, according to a preferred embodiment of the present invention;

FIG. 11 is a diagrammatic view illustrating the first exemplary embodiment of the high-current switch of FIG. 1, according to a preferred embodiment of the present invention; and

FIG. 12 is a diagrammatic view illustrating a second exemplary embodiment of the high-current switch of FIG. 1, according to a preferred embodiment of the present invention.

### DETAILED DESCRIPTION OF THE INVENTION

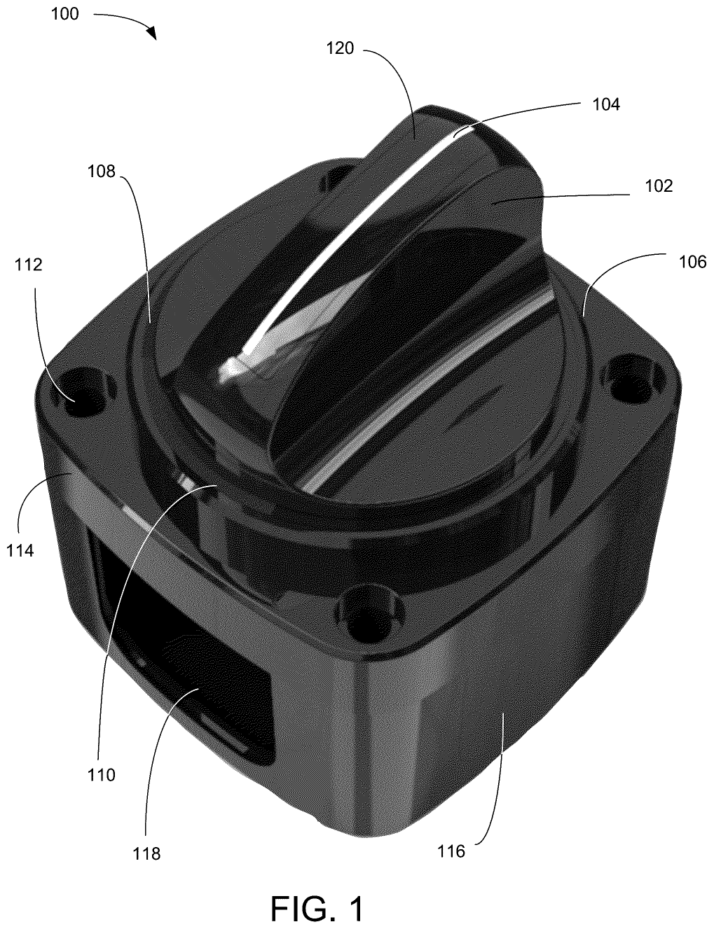

As used and defined herein, words of relative position such as “front”, “bottom”, etc. refer to the apparatus in the operational orientation shown in FIG. 1. The hundred(s) digits of reference numbers refer to the drawing number in regard to which the referenced item is first shown and discussed. As used and defined herein, “LED” means “light emitting diode” and “PCB” means “printed circuit board”.

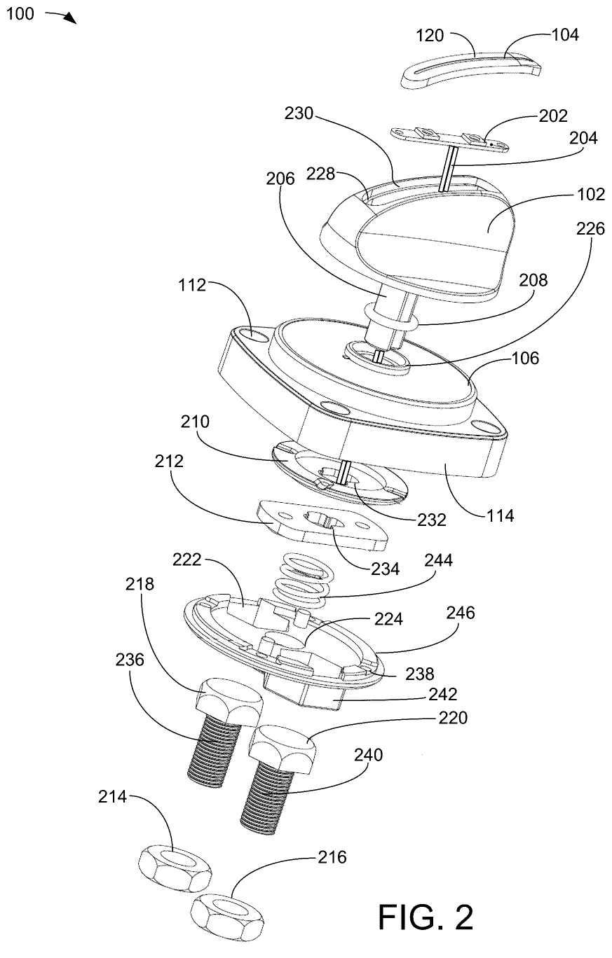

FIG. 1 is a photographic top rear perspective view illustrating an exemplary embodiment of a high-current switch 100 on an exemplary embodiment of a switch housing 116, according to a preferred embodiment of the present invention. Switch housing 116 has an opening 118 to accommodate high-current wires to connect to the switch poles 236 and 240 (see FIG. 2), exemplified in FIG. 2 as bolts 236 and 240. Rotary knob 102 has an LED cover 120 which has a transparent or translucent centerline window 104 through which light from underlying LEDs may emit light. Window 104 may be transparent or translucent. The illustrated size and shape of the centerline strip is not a limitation of the invention, as various sizes and shapes of transparent strips may be used in respective various embodiments. Switch housing 116 supports an electrically non-conductive switch top cover 114 having fastener receivers 112, exemplified here as bolt holes 112 (one of four labeled), for securing the high-current switch 100 to the switch housing 116 and optionally to an environmental structure, when installed. Switch top cover 114 supports a disc-shaped plateau 106 which supports the rotary knob 102. Plateau 106 has a larger diameter than the flared base of rotary knob 102 to accommodate a permanent red arcuate strip 110 to indicate an OFF position of the high-current switch 100 and a permanent blue arcuate strip 108 to indicate an ON position of the high-current switch 100 on top of the plateau 106. The rotary knob 102 has ninety degrees of freedom in rotation.

FIG. 2 is an exploded perspective view illustrating the exemplary embodiment of the high-current switch 100 of FIG. 1, according to a preferred embodiment of the present invention. PCB 202 includes LEDs of the RGB or RGBW variety, which are controlled by a processor on the PCB 202. The LEDs are turned ON by the micro controller when the rotary knob 102 is turned to the ON position. The LEDs are turned OFF by the micro controller when the rotary knob 102 is turned to the OFF position. First and second insulated wires 204 are attached to and supply low-current power to the PCB 202. PCB 202 also includes a microcontroller (MCU) to evaluate high-current voltage to make the LEDs flash red if the high-current voltage falls below a predetermined level. Rotary knob 102 has a top opening 230 with a recessed perimeter shelf 228 upon which the PCB 202 and the LED cover 120 rests, when assembled. Rotary knob 102 has a height sufficient to distance the PCB 202 from the heat generated from the electrically conductive block 212 of the high-current switch 100. Conductive block 212 may be, for non-limiting example, brass. Rotary knob 102 is preferably molded as a single piece of plastic, including an axle 206 that has a cross section that is not circular. A water-resistant seal 208 on axle 206 sits in and seals with seal receiver 226 on plateau 106 of switch top cover 114. Plateau 106, switch top cover 114, seal receiver 226, and fastener receivers 112 are preferably made of one piece of thermally and electrically insulative molded plastic.

Axle 206 extends through seal receiver 226 and through a central opening 232 of rotational disc 210. Central opening 232 has a shape corresponding to the cross-sectional shape of axle 206 such that rotary knob 102 rotates rotational disc 210 without rotating switch top cover 114. Axle 206 also extends through central opening 234 of electrically conductive block 212. Central opening 234 has a shape corresponding to the cross-sectional shape of axle 206 such that rotary knob 102 rotates conductive block 212. Conductive block 212, when high-current switch 100 is assembled will, in the ON position, contact bolt heads 218 and 220, thereby completing a circuit between the bolts 236 and 240. In the OFF position, conductive block 212 will contact neither bolt head 218 nor bolt head 220. Coil spring 244 biases conductive block 212 upward. Coil spring 244 is based in cup 224. Bolts 236 and 240, which are the electrical poles of high-current switch 100, are inserted from above switch base 246 and through openings in the bolt head chambers 222 and 242, respectively, of switch base 246. Bolt head 218, when installed, extends slightly above the upper edge of bolt head chamber 242 and bolt head 220, when installed, extends slightly above the upper edge of bolt head chamber 242. When the high-current switch 100 is turned to the ON position, conductive block 212 conductively engages the bolt heads 218 and 220. When the high-current switch 100 is turned to the OFF position, conductive block 212 does not conductively engage the bolt heads 218 and 220. Conductive block 212 may be made of brass or similarly conductive and heat resistive metal. Switch base 246 is assembled fixedly attached to the underside of switch top cover 114 using fastener receivers 238 (one of four labeled). Once bolts 236 and 240 are installed in bolt head chambers 222 and 242, respectively, first and second high-current electrical wires are connected to first and second bolts 236 and 240 and nuts 214 and 216 secure first and second high-current wires to the first and second bolts 236 and 240, respectively. Bolts 236 and 240 are the poles of the high-current switch 100.

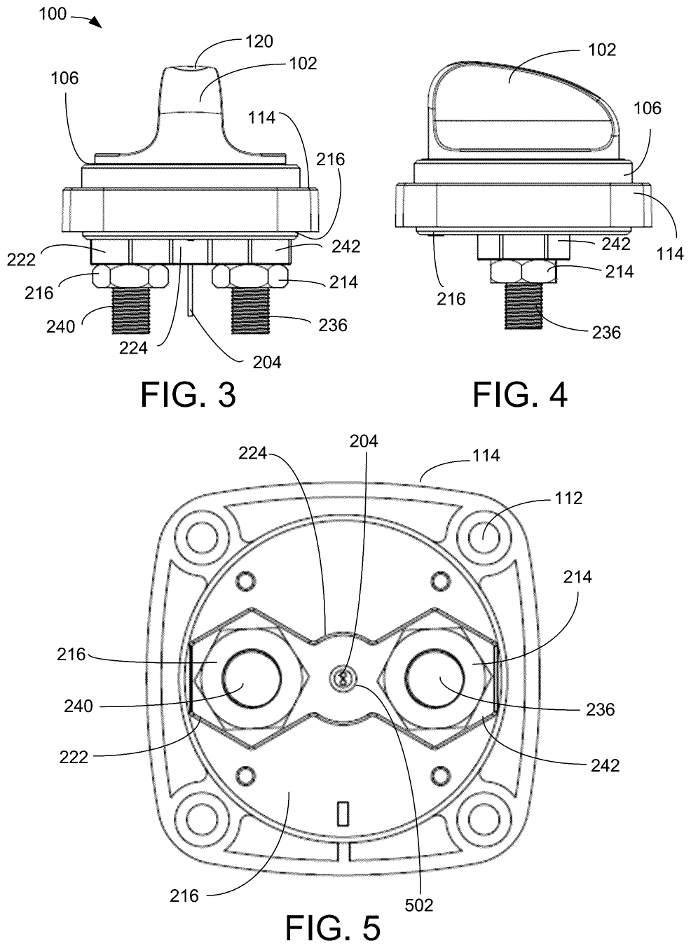

FIG. 3 is a front elevation view illustrating the exemplary embodiment of the high-current switch 100 of FIG. 1, according to a preferred embodiment of the present invention. When electrically connected to a high-current circuit, first and second high-current wires connect between nut 216 and the bottom of blot head chamber 222 and between nut 214 and the bottom surface of bolt head chamber 242, respectively. A conductive lock washer may advantageously be used in some embodiments. The first and second high-current wires extend through opening 118 of switch housing 116 when fully assembled into a high-current circuit.

FIG. 4 is a side elevation view illustrating the exemplary embodiment of the high-current switch 100 of FIG. 1, according to a preferred embodiment of the present invention. Bolt 236 and bolt 240 are preferably aligned, side-by-side with separation sufficient to avoid arcing between bolts 240 and 236,

FIG. 5 is a bottom plan view illustrating the exemplary embodiment of the high-current switch 100 of FIG. 1, according to a preferred embodiment of the present invention. Conduit 502 through switch base 246 conducts insulated wires 204. Bolt head chambers 222 and 242 can be more clearly seen in this view.

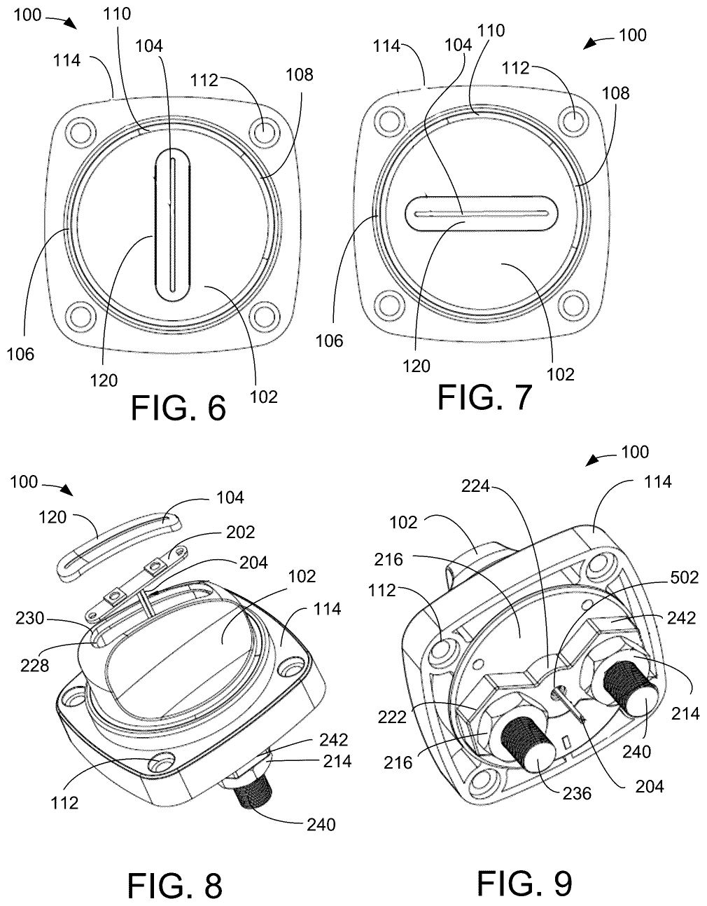

FIG. 6 is a top plan view illustrating the exemplary embodiment of the high-current switch 100 of FIG. 1 in an OFF position, according to a preferred embodiment of the present invention.

FIG. 7 is a top plan view illustrating the high-current switch 100 of FIG. 1 in an ON position, according to a preferred embodiment of the present invention. The colors displayed by the LEDs may vary among respectively various embodiments, particularly for various cultural markets where the ON and alarm colors are different. Rotary knob 102 has been rotated clockwise, relative to the position in FIG. 6, to close a high-current circuit.

FIG. 8 is a top perspective view illustrating the exemplary embodiment of the high-current switch 100 of FIG. 1, according to a preferred embodiment of the present invention.

FIG. 9 is a bottom perspective view illustrating the exemplary embodiment of the high-current switch 100 of FIG. 1, according to a preferred embodiment of the present invention. The fixed relationship of the switch base 246 to the underside of the switch top cover 114 can be more clearly seen in this view.

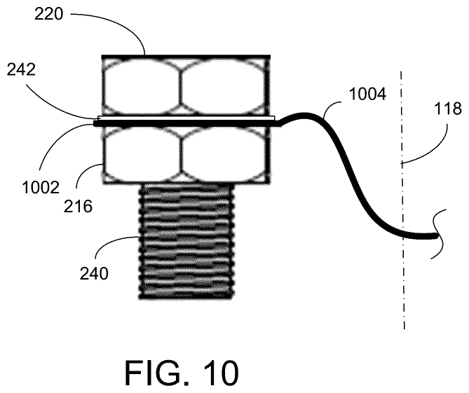

FIG. 10 is a cutaway side elevation view illustrating an exemplary embodiment of a high-current insulated wire 1004 connected to an exemplary pole 240 of the high-current switch 100 of FIG. 1, according to a preferred embodiment of the present invention. High-current insulated wire 1004 terminates in a bare metal flat connector 1002, which may be an annular connector or a “C” connector, for non-limiting examples. Flat connector 1002 is sandwiched between nut 216 and the bottom of bolt head chamber 242 supported from above by bolt head 220. High-current wire 1004 extends out opening 118 or switch housing 116 and to a high-current circuit.

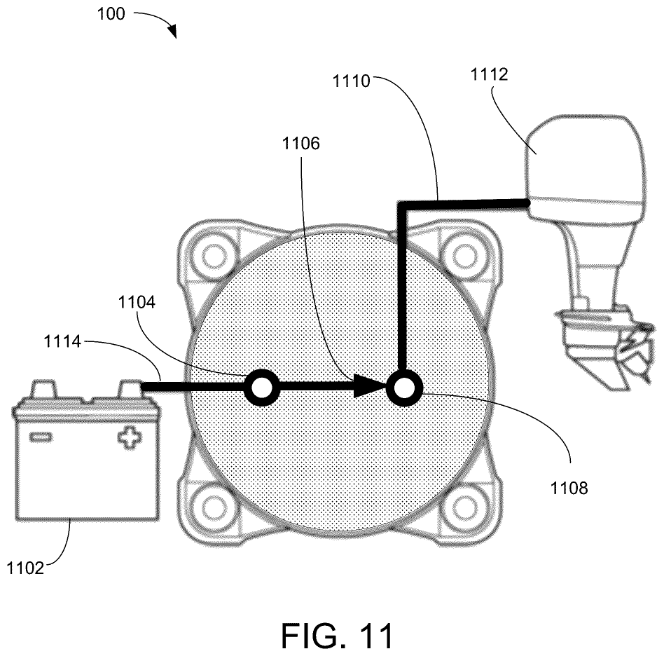

FIG. 11 is a diagrammatic view illustrating the first exemplary embodiment of the high-current switch 100 of FIG. 1, according to a preferred embodiment of the present invention. Battery 1102 is connected to switch pole 1104 by wire 1114. Switch pole 1104 is connected to switch pole 1108 by moveable conductor 1106 (such as conductive block 212), shown in the ON position. Switch pole 1108 connects to the load 1112 via wire 1110. In the OFF position, moveable conductor 1106 is rotated out of contact with switch pole 1108.

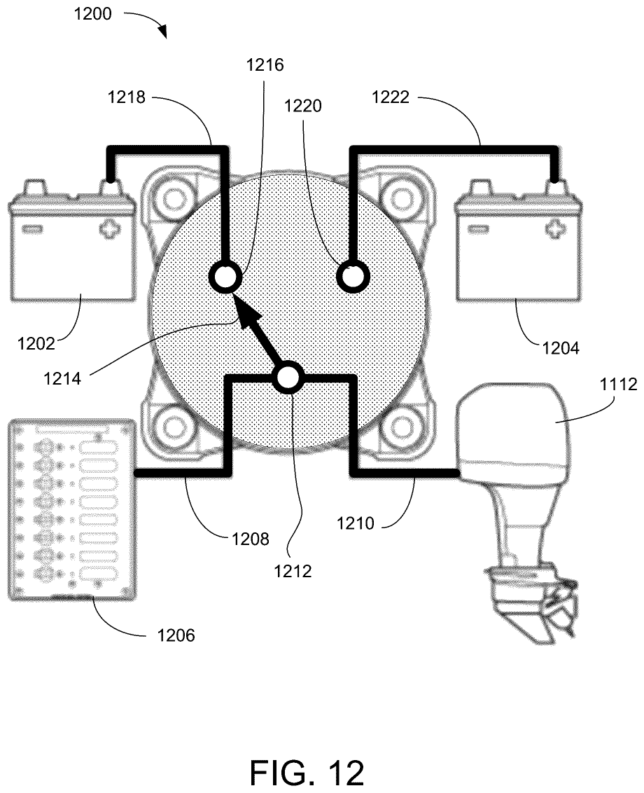

FIG. 12 is a diagrammatic view illustrating a second exemplary embodiment of a high-current switch 1200, according to a preferred embodiment of the present invention. High-current switch 1200 controls either of two batteries 1202 and 1204 to supply loads 1206 and 1112. In the illustrated position, moveable conductor 1214 connects to load 1206 via switch pole 1212 and conductor 1208 as well as to load 1112 via switch pole 1212 and conductor 1210. In this configuration, the PCB 202 monitors the voltage of battery 1202 and displays LED light through window 104. In a second ON position, moveable conductor 1214 connects to switch pole 1220 receive high-current electricity from battery 1204 via conductor 1222. In this configuration, the PCB 202 monitors the voltage of battery 1204 and displays LED light through window 104. In a third position of moveable conductor 1214, neither switch pole 1216 nor 1220 is connected to the loads 1206 and 1112. In this OFF configuration, no voltage is monitored and the LED lights are off. For high-current switch 1200, the colors for the permanent arcuate strips 108 and 110 would be adapted to have two colors for ON, one for each battery 1202 and 1204, and one color for OFF.

Those of skill in the art, enlightened by the present disclosure, will be aware that the high-current switch 1200 may be extended to yet even more batteries 1202 and 1204 and to yet even more loads 1206 and 1112.

The following claims may contain functional claim language and do not contain statements of intended use.

We claim:

1. A high-current switch with three-state illuminated knob comprising:
a. a rotary knob on an electrical switch for currents above twenty-five amperes;
b. a PCB with a plurality of LEDs, a high-current voltage detector, and a microprocessor housed in said knob beneath a cover having an at least partially transparent window;
c. said microprocessor operable to receive an input from said voltage detector and operable to turn OFF said plurality of LEDs when said switch is OFF, turn ON at least one LED of said plurality of LEDs when said switch is ON, and control said LEDs to flash if said detected voltage falls below a predetermined level.

2. The high-current switch of claim 1, comprising:
a. an axle, having a non-circular cross-section, extending from said rotary knob and having a water-resistant seal around said axle;
b. and a lumen longitudinally arranged in said axle, operable to conduct wires for supplying power to said PCB.

3. The high-current switch of claim 2, comprising a switch top cover having an opening to translationally receive and rotationally conduct said axle, wherein said opening is surrounded by a receiver for said seal, on a plateau upon which said knob rests and may rotate.

4. The high-current switch of claim 3, comprising a plurality of permanently color-coded permanent arcuate strips proximate a perimeter of said plateau corresponding at least to:
a. said OFF position of said rotary knob; and
b. said ON position of said rotary knob.

5. The high-current switch of claim 3, comprising a plurality of fastener receivers in said switch top cover operable to assist in fastening said switch top cover to a switch housing.

6. The high-current switch of claim 5, wherein said switch housing has an opening for conducting a plurality of high-current wires attachable to a respective plurality of switch poles of said high-current switch.

7. The high-current switch of claim 3, comprising a rotational disc slidingly in contact with an underside of said switch top cover and having a central opening having a non-circular cross section corresponding to said non-circular cross section of said axle, such that said rotational disc rotates with said axle.

8. The high-current switch of claim 7, comprising a conductive, generally rectangular, block having a central opening having a non-circular cross section corresponding to said non-circular cross section of said axle, such that said conductive block rotates with said axle.

9. The high-current switch of claim 8, comprising a non-conductive switch base:
a. fastenable to said underside of said switch top cover;
b. having:
i. a plurality of bolt head chambers operable to receive a respective plurality of switch poles;
ii. a support for a biasing element; and
iii. a conduit for PCB power wires.

10. The high-current switch of claim 9, wherein said plurality of switch poles comprise bolts with nuts.

11. A high-current switch with three-state illuminated knob comprising:
a. a rotary knob on an electrical switch for currents above twenty-five amperes;
b. a PCB with a plurality of LEDs, a voltage meter, and a microprocessor housed in said knob beneath a cover having an at least partially transparent window;
c. said microprocessor receiving an input from said voltage meter and operable to turn OFF said plurality of LEDs when said switch is OFF, turn ON at least one LED of said plurality of LEDs when said switch is ON, and control said LEDs to flash if said voltage falls below a predetermined level;
d. an axle, having a non-circular cross-section, extending from said rotary knob and having a water-resistant seal around said axle;
e. a lumen longitudinally through said axle operable to conduct ground and VCC insulated wires for powering said PCB; and
f. an electrically non-conductive switch top cover having an opening to translationally receive and rotationally conduct said axle, wherein said opening is surrounded by a receiver for said seal, on a plateau upon which said knob rests and may rotate.

12. The high-current switch of claim 11, comprising:
a. a plurality of permanently color-coded portions proximate a perimeter of said plateau corresponding firstly to said OFF position of said rotary knob and secondly to said ON position of said rotary knob;
b. a plurality of fastener receivers in said switch top cover operable to assist in fastening said switch top cover to a switch housing; and
c. wherein said switch housing has an opening for conducting a plurality of high-current wires attachable to a respective plurality of switch poles of said high-current switch.

13. The high-current switch of claim 12, comprising a rotational disc slidingly in contact with an underside of said switch top cover and having a central opening having a non-circular cross section corresponding to said non-circular cross section of said axle, such that said rotational disc rotates with said axle.

14. The high-current switch of claim 13, comprising a conductive, generally rectangular, block having a central opening having a non-circular cross section corresponding to said non-circular cross section of said axle, such that said conductive block rotates with said axle.

15. The high-current switch of claim 8, comprising a non-conductive switch base:
a. fastenable to said underside of said switch top cover;
b. having:
i. a plurality of bolt head chambers operable to receive a respective plurality of switch poles;
ii. a support for a biasing element; and
c. a conduit for PCB ground and VCC wires.

16. The high-current switch of claim 15, wherein:
a. each switch pole of said plurality of switch poles comprises a bolt with a nut; and
b. said biasing element comprises a coil spring.

17. A high-current switch with three-state illuminated knob comprising:
a. a plurality of high-current electrical switch poles operable to conduct electrical currents above twenty-five amperes;
b. a rotary knob extending away from said plurality of electrical switch poles;
c. a PCB housed in a portion of said rotary knob distal said plurality of electrical switch poles;
d. a plurality of LEDs mounted on said PCB;
e. a cover for said plurality of LEDs inset in said distal portion of said rotary knob;
f. a portion of said cover comprising one of transparent and translucent material;
g. a microprocessor mounted on said PCB, operable to:
i. turn said LEDs OFF when said rotary knob is in an OFF position;
ii. turn at least one LED ON when said rotary knob is in an ON position;
iii. sense a low-current indication of the voltage of the high-current conducted through said high-current switch;
iv. determine if said voltage indication indicates a voltage below a predetermined value; and
v. if said voltage indication is below said predetermined value, control at least one LED to flash;
h. an axle, having a non-circular cross-section, extending from and fixed to said rotary knob and having a water-resistant seal around said axle;
i. a lumen through said axle operable to conduct insulated wired to power said PCB; and
j. an electrically non-conductive switch top cover having an opening to translationally receive and rotationally conduct said axle, wherein said opening is surrounded by a receiver for said seal, on a plateau upon which said knob rests and may rotate.

18. The high-current switch of claim 17, comprising:
a. a plurality of permanently color-coded permanent arcuate strips on said plateau, proximate a perimeter of said plateau, corresponding at least to said OFF position of said rotary knob and to said ON position of said rotary knob;
b. a plurality of fastener receivers in said switch top cover operable to assist in fastening said switch top cover to a switch housing;
c. wherein said switch housing has an opening for conducting a plurality of high-current wires attachable to a respective plurality of switch poles of said high-current switch;
d. a rotational disc slidingly in contact with an underside of said switch top cover and having a central opening having a non-circular cross section corresponding to said non-circular cross section of said axle, such that said rotational disc rotates with said axle; and
e. a conductive, generally rectangular, block having a central opening having a non-circular cross section corresponding to said non-circular cross section of said axle, such that said conductive block rotates with said axle.

19. The high-current switch of claim 18, comprising a non-conductive switch base:
a. fastenable to said underside of said switch top cover;
b. having:
i. a plurality of bolt head chambers operable to receive a respective plurality switch poles;
ii. a support for a biasing element; and
iii. a conduit for voltage detection wires.

20. The high-current switch of claim 19, wherein:
a. each said switch pole of said plurality of switch poles comprise a bolt with a nut; and
b. said biasing element comprises a coil spring.
